(19) United States
(12) Patent Application Publication
(10) Pub. No.: US 2025/0318348 A1
(43) Pub. Date: Oct. 9, 2025

(54) DISPLAY PANEL AND DISPLAY DEVICE

(71) Applicant: WUHAN TIANMA MICROELECTRONICS CO., LTD. SHANGHAI BRANCH, Shanghai (CN)

(72) Inventor: Xi CHEN, Shanghai (CN)

(21) Appl. No.: 19/241,363

(22) Filed: Jun. 17, 2025

(30) Foreign Application Priority Data
Feb. 18, 2025 (CN) 202510179887.3

(51) Int. Cl. H10H 29/853; H01L 25/075; H10H 29/45; H10H 29/49

(52) U.S. Cl. CPC H10H 29/853; H01L 25/0753; H10H 29/45; H10H 29/49

(57) ABSTRACT

Provided are a display panel and a display device. The display panel includes a first substrate and a second substrate opposite to each other, where the first substrate includes a first elastic layer, a first buffer layer and a plurality of first encapsulation structures, the first encapsulation structures respectively include at least one first-type sub-pixel; and the second substrate includes a second elastic layer, a second buffer layer, and a plurality of second encapsulation structures, the second encapsulation structures respectively include at least one second-type sub-pixel. The display panel includes a first region and a second region, and the first region and the second region are arranged along a first direction; and in the first region and/or the second region, the first buffer layer and the second buffer layer have different stretching amounts in a same direction.

### CROSS-REFERENCE TO RELATED APPLICATIONS

The present application claims priority to Chinese Patent Application No. 202510179887.3, filed on Feb. 18, 2025, the content of which is incorporated herein by reference in its entirety.

### TECHNICAL FIELD

The present disclosure relates to the field of display technologies, and in particular, to a display panel and a display device.

### BACKGROUND

In the field of display technologies, a stretchable display panel can meet use requirements of consumers in different scenarios due to expansion or compression of a display area and has become the focus of research by various manufacturers in recent years.

However, in the related art, the resolution of the stretchable display panel is relatively low when it is stretched for display, resulting in poor display quality. Therefore, a solution is urgently needed.

### SUMMARY

Embodiments of the present disclosure provide a display panel and a display device to solve the above-mentioned problems.

In a first aspect, an embodiment of the present disclosure provides a display panel, including a first substrate and a second substrate opposite to each other, where the first substrate includes a first elastic layer, a first buffer layer and a plurality of first encapsulation structures, the plurality of first encapsulation structures respectively include at least one first-type sub-pixel, the first buffer layer is located between the first elastic layer and the plurality of first encapsulation structures, and the plurality of first encapsulation structures are located on a side of the first elastic layer facing the second substrate; and the second substrate includes a second elastic layer, a second buffer layer, and a plurality of second encapsulation structures, plurality of the second encapsulation structures respectively include at least one second-type sub-pixel, the second buffer layer is located between the second elastic layer and the plurality of second encapsulation structures, and the plurality of second encapsulation structures is located on a side of the second elastic layer facing the first substrate. The display panel includes a first region and a second region, and the first region and the second region are arranged along a first direction; and in the first region and/or the second region, the first buffer layer and the second buffer layer have different stretching amounts in a same direction.

In a second aspect, an embodiment of the present disclosure provides a display device including the display panel described in the first aspect.

In the embodiments of the present disclosure, in the first region and/or the second region, stretching amounts of the first buffer layer and the second buffer layer in a same direction are different. As a result, when the display panel is stretched, in the first region and/or the second region, the first buffer layer and the second buffer layer respectively drive the first encapsulation structure and the second encapsulation structure to move different distances, so that first-type sub-pixels in the first encapsulation structures and second-type sub-pixels in the second encapsulation structures are staggered from each other in a direction perpendicular to a plane where the display panel is arranged, which is beneficial for exposing the second-type sub-pixels after the display panel is stretched, to increase the number of sub-pixels for displaying a picture after the display panel is stretched, thereby improving the resolution of the display picture after the display panel is stretched, and improving the display quality.

### BRIEF DESCRIPTION OF DRAWINGS

In order to illustrate the technical solutions in the embodiments of the present disclosure more clearly, the drawings, which are intended to be used in the description of the embodiments, are briefly described as below. It will be apparent that other drawings described below are merely some embodiments of the present disclosure, and other drawings may be obtained by those skilled in the art according to these drawings without paying any creative efforts.

FIG. 1 is a structural schematic diagram of a display panel in a contracted state according to an embodiment of the present disclosure;

FIG. 2 is a structural schematic diagram of a display panel in a stretched state according to an embodiment of the present disclosure;

FIG. 3 is a plane comparison schematic diagram of a first substrate and a second substrate according to an embodiment of the present disclosure;

FIG. 4 is another structural schematic diagram of a display panel in a contracted state according to an embodiment of the present disclosure;

FIG. 5 is a structural schematic diagram of a film layer of a sub-pixel according to an embodiment of the present disclosure;

FIG. 6 is a structural schematic diagram of a film layer of a connection structure according to an embodiment of the present disclosure;

FIG. 7 is another plane comparison schematic diagram of a first substrate and a second substrate according to an embodiment of the present disclosure;

FIG. 8 is another schematic structural diagram of a display panel in a contracted state according to an embodiment of the present disclosure;

FIG. 9 is another schematic structural diagram of a display panel in a contracted state according to an embodiment of the present disclosure;

FIG. 10 is another plane comparison schematic diagram of a first substrate and a second substrate according to an embodiment of the present disclosure;

FIG. 11 is another plane comparison schematic diagram of a first substrate and a second substrate according to an embodiment of the present disclosure;

FIG. 12 is another plane comparison schematic diagram of a first substrate and a second substrate according to an embodiment of the present disclosure;

FIG. 13 is another plane comparison schematic diagram of a first substrate and a second substrate according to an embodiment of the present disclosure;

FIG. 14 is another plane comparison schematic diagram of a first substrate and a second substrate according to an embodiment of the present disclosure;

FIG. 15 is another plane comparison schematic diagram of a first substrate and a second substrate according to an embodiment of the present disclosure; and

FIG. 16 is a schematic diagram of a display device according to an embodiment of the present disclosure.

### DESCRIPTION OF EMBODIMENTS

In order to better understand technical solutions of the present disclosure, embodiments of the present disclosure are described in detail below in conjunction with the drawings.

It should be clear that the embodiments described are only some rather than all of the embodiments of the present disclosure. Based on the embodiments of the present disclosure, all other embodiments obtained by those ordinary skilled in the art without creative efforts shall fall within the protection scope of the present disclosure.

The terms used in the embodiments of the present disclosure are only for the purpose of describing specific embodiments and are not intended to limit the present disclosure. Unless otherwise noted in the context, the singular form expressions “a/an”, “the”, and “said” used in the embodiments and appended claims of the present disclosure are also intended to represent plural form expressions thereof.

It should be understood that the term “and/or” used herein is merely an association relationship describing an associated object, indicating that there may be three relationships, for example, A and/or B, and may indicate: only A, both A and B, and only B. In addition, the character “/” herein generally means an “or” relationship between the associated objects.

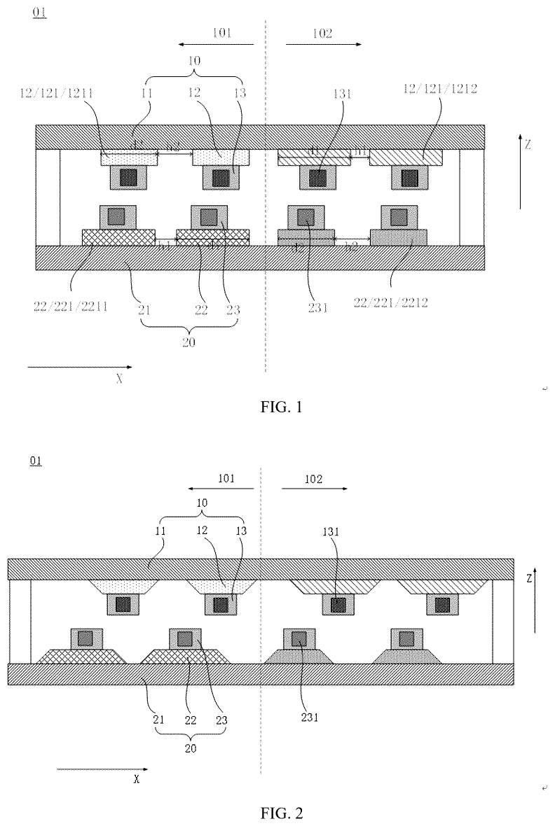

FIG. 1 is a structural schematic diagram of a display panel in a contracted state according to an embodiment of the present disclosure, and FIG. 2 is a structural schematic diagram of a display panel in a stretched state according to an embodiment of the present disclosure.

An embodiment of the present disclosure provides a display panel 01, and the display panel 01 is a stretchable display panel. As shown in FIG. 1 and FIG. 2, the display panel 01 includes a first substrate 10 and a second substrate 20 opposite to each other. The first substrate 10 includes a first elastic layer 11, a first buffer layer 12 and a plurality of first encapsulation structures 13, and each first encapsulation structure 13 includes at least one first-type sub-pixel 131. The first buffer layer 12 is located between the first elastic layer 11 and the first encapsulation structures 13, and the first encapsulation structures 13 are located on a side of the first elastic layer 11 facing the second substrate 20.

The first elastic layer 11 may be a flexible substrate in the first substrate 10, including a stretchable polymer. Alternatively, the first elastic layer 11 includes at least one of silicone elastomer, polyurethane, polydimethylsiloxane, thermoplastic polyurethane elastomer rubber, thermoplastic polyimide, copolyester, polycarbonate (PC), polyethersulfone (PES), polyethylene terephthalate (PET), polyethylene naphthalate (PEN), polyarylate (PAR), and fiberglass reinforced plastic (FRP).

Alternatively, the first buffer layer 12 is arranged on the first elastic layer 11, and the first encapsulation structures 13 are arranged on the first buffer layer 12. The first buffer layer 12 includes an elastic organic material.

The second substrate 20 includes a second elastic layer 21, a second buffer layer 22, and a plurality of second encapsulation structures 23, and each second encapsulation structure 23 includes at least one second-type sub-pixel 231. The second buffer layer 22 is located between the second elastic layer 21 and the second encapsulation structures 23, and the second encapsulation structures 23 are located on a side of the second elastic layer 21 facing the first substrate 10.

For example, both the first-type sub-pixels 131 and the second-type sub-pixels 231 may each include a red sub-pixel, a green sub-pixel, and a blue sub-pixel.

The second elastic layer 21 may be a flexible substrate in the second substrate 20, including a stretchable polymer. Alternatively, the second elastic layer 21 includes at least one of silicone elastomer, polyurethane, polydimethylsiloxane, thermoplastic polyurethane elastomer rubber, thermoplastic polyimide, copolyester, polycarbonate (PC), polyethersulfone (PES), polyethylene terephthalate (PET), polyethylene naphthalate (PEN), polyarylate (PAR), and fiberglass reinforced plastic (FRP).

For example, the second elastic layer 21 and the first elastic layer 11 are made of the same material.

Alternatively, the second buffer layer 22 is arranged on the second elastic layer 21, and the second encapsulation structures 23 are arranged on the second buffer layer 22. The second buffer layer 22 includes an elastic organic material.

The display panel 01 includes a first region 101 and a second region 102. The first region 101 and the second region 102 are arranged along a first direction X, and the first direction X is parallel to a plane where the display panel 01 is arranged. In the first region 101 and/or the second region 102, the first buffer layer 12 and the second buffer layer 22 have different stretching amounts in a same direction.

For example, when the display panel 01 is stretched along the first direction X, in the first region 101 and/or the second region 102, the first buffer layer 12 and the second buffer layer 22 have different stretching amounts in the first direction X.

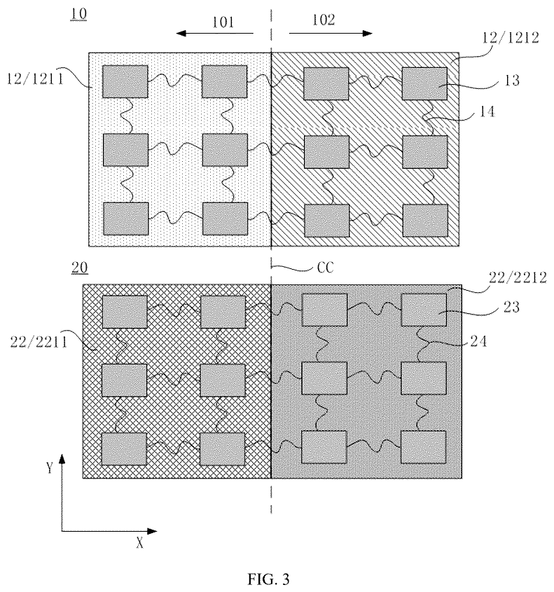

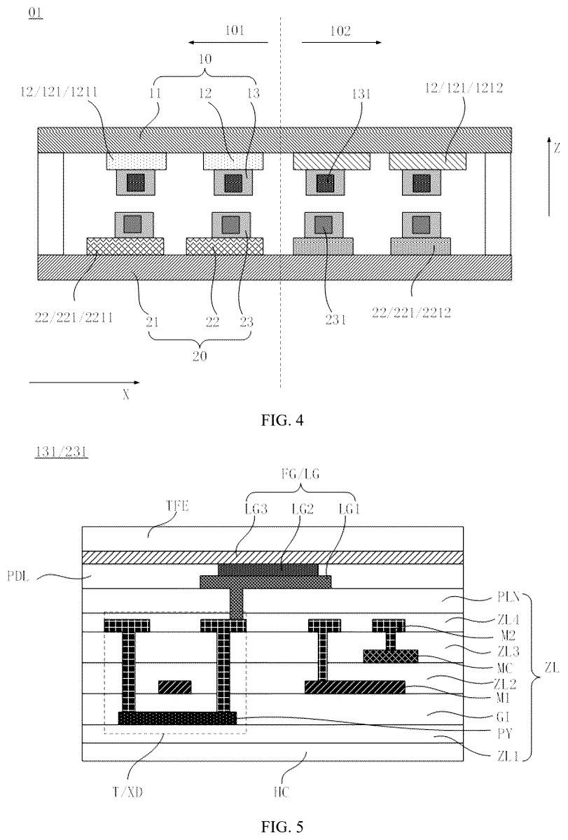

Alternatively, as shown in FIG. 3, which is a plane comparison schematic diagram of a first substrate and a second substrate according to an embodiment of the present disclosure, the display panel 01 includes a first virtual central axis CC extending along a second direction Y, and the second direction Y intersects with the first direction X. The first region 101 and the second region 102 are arranged on two opposite sides of the first virtual central axis CC.

It should be noted that, for clarity of illustration, FIG. 3 only illustrates the first buffer layer 12 and the first encapsulation structures 13 in the first substrate 10, and the second buffer layer 22 and the second encapsulation structures 23 in the second substrate 20.

In the embodiments of the present disclosure, in the first region 101 and/or the second region 102, stretching amounts of the first buffer layer 12 and the second buffer layer 22 in the same direction are set to be different, so that when the display panel 01 is stretched, in the first region 101 and/or the second region 102, the first buffer layer 12 and the second buffer layer 22 respectively drive the first encapsulation structure 13 and the second encapsulation structure 23 to move different distances, which is beneficial for staggering the first-type sub-pixels 131 in the first encapsulation structures 13 and the second-type sub-pixels 231 in the second encapsulation structures 23 from each other in a direction Z perpendicular to a plane where the display panel 01 is arranged, which is further beneficial for exposing the second-type sub-pixels 231 after the display panel 01 is stretched, to increase the number of sub-pixels for displaying a picture after the display panel 01 is stretched, thereby improving the resolution of the display picture after the display panel 01 is stretched, and improving the display quality.

For example, in combination with in FIG. 1 and FIG. 2, the first-type sub-pixels 131 can be formed as a bottom light-emitting structure, and the first-type sub-pixels 131 emit light toward a side of the first elastic layer 11; and the second-type sub-pixels 231 can be formed as a top light-emitting structure, and the second-type sub-pixels 231 emit light toward a side of the first elastic layer 11. In the contracted state of the display panel 01, the first-type sub-pixels 131 emit light, and the second-type sub-pixels 231 do not emit light; and in the stretched state of the display panel 01, both the first-type sub-pixels 131 and the second-type sub-pixels 231 emit light. In this way, after the display panel 01 is stretched, the first-type sub-pixels 131 and the second-type sub-pixels 231 can be displayed in a staggered manner, increasing the number of sub-pixels for displaying the image, thereby improving the resolution of the display panel 01 in the stretched state.

Alternatively, the display panel 01 includes a contracted state and a stretched state. As shown in FIG. 1, in the contracted state, the first encapsulation structure 13 at least partially overlaps with the second encapsulation structure 23 in the direction Z perpendicular to the plane where the display panel 01 is arranged.

For example, as shown in FIG. 1, along the direction Z perpendicular to the plane where the display panel 01 is arranged, the first encapsulation structure 13 partially overlaps with the second encapsulation structure 23.

For example, as shown in FIG. 4, which is another structural schematic diagram of a display panel in a contracted state according to an embodiment of the present disclosure, along the direction Z perpendicular to the plane where the display panel 01 is arranged, a projection of the first encapsulation structure 13 coincides with a projection of the second encapsulation structure 23 on the same plane.

As shown in FIG. 2, in the stretched state, the first encapsulation structures 13 does not overlap with the second encapsulation structures 23 in the direction Z perpendicular to the plane where the display panel 01 is arranged.

Based on this arrangement manner, on one hand, it is beneficial to ensure that more first encapsulation structures 13 and more second encapsulation structures 23 can be provided in the display panel 01 in the contracted state, thereby facilitating ensuring that the display panel 01 has a higher display resolution in the contracted state. On the other hand, while improving the display resolution of the display panel 01 in the stretched state, it is beneficial to avoid the problem of light interference between the first-type sub-pixels 131 in the first encapsulation structures 13 and the second-type sub-pixels 231 in the second encapsulation structures 23, thereby further improving the display quality.

In some embodiments, as shown in FIG. 3, the first substrate 10 further includes a first connection structure 14 electrically connected to two adjacent first encapsulation structures 13, and the first connection structure 14 includes a plurality of signal traces that can be configured to transmit electrical signals to the first-type sub-pixels 131 in the first encapsulation structures 13. Alternatively, the first connection structure 14 is arranged on the first buffer layer 12.

The second substrate 20 further includes a second connection structure 24 electrically connected to two adjacent second encapsulation structures 23, and the second connection structure 24 includes a plurality of signal traces that can be configured to transmit electrical signals to the second-type sub-pixels 231 in the second encapsulation structures 23. Alternatively, the second connection structure 24 is arranged on the second buffer layer 22.

For example, the first connection structure 14 and the second connection structure 24 may both include, for example, a scan signal line, a data signal line, a sensing signal line, and the like. The forming material of the film layer where the signal lines are arranged may include, for example, at least one or more of molybdenum, aluminum, silver, and indium tin oxide (ITO).

In the embodiments of the present disclosure, the first connection structure 14 and the second connection structure 24 can transmit signals for display to the first-type sub-pixels 131 and the second-type sub-pixels 231, respectively, to meet requirements of normal display of the first-type sub-pixels 131 and the second-type sub-pixels 231.

Moreover, when the display panel 01 is stretched for display, the signal lines in the first connection structure 14 and the second connection structure 24 can be used to provide feedback signals to a control system. The control system controls the first-type sub-pixels 131 and the second-type sub-pixels 231 to emit light according to the feedback signals, thereby increasing the resolution of the display panel 01 when it is stretched for display.

It should be understood that, the control system can also determine whether the display panel 01 is in the stretched state or the contracted state according to other conditions, to control light-emitting states of the first-type sub-pixels 131 and the second-type sub-pixels 231 according to actual needs.

FIG. 5 is a structural schematic diagram of a film layer of a sub-pixel according to an embodiment of the present disclosure.

In some embodiments, both the film layer structures of the first-type sub-pixels 131 and the second-type sub-pixels 231 can be as shown in FIG. 5, including an array layer ZL and a light-emitting device layer FG located on a side of the array layer ZL away from a buffer layer HC. In the diagram of the film layer structure of the first-type sub-pixels 131, the buffer layer HC may be the first buffer layer 12. In the diagram of the film layer structure of the second-type sub-pixels 231, the buffer layer HC may be the second buffer layer 22.

The array layer ZL includes a plurality of transistors T, and the plurality of transistors T may constitute a pixel circuit XD. The light-emitting device layer FG includes a light-emitting unit LG, and the light-emitting unit LG includes an anode LG1, a light-emitting layer LG2, and a cathode LG3 that are stacked. The cathode LG3 is located on a side of the light-emitting layer LG2 away from the array layer ZL, and at least part of the light-emitting layer LG2 can be arranged in an opening of a pixel definition layer PDL. A side of the cathode LG3 away from the light-emitting layer LG2 is provided with an encapsulation layer TFE for protecting internal devices.

The pixel circuit XD is electrically connected to the anode LG1, and can be configured to provide a light-emitting driving signal to the light-emitting unit LG.

It should be noted that FIG. 5 only shows one transistor T in the pixel circuit XD.

For example, as shown in FIG. 5, the array layer ZL may include a first inorganic layer ZL1, a semiconductor layer PY, a gate insulating layer G1, a first metal layer M1, a capacitor dielectric layer ZL2, a capacitor plate layer MC, an intermediate dielectric layer ZL3, a second metal layer M2, a second inorganic layer ZL4, and a planarization layer PLN that are stacked. The transistor T has a gate located in the first metal layer M1, and a source-drain electrode located in the second metal layer M2. The first inorganic layer ZL1 can be directly arranged on the buffer layer HC.

If the sub-pixel is formed as a top light-emitting structure, the anode LG1 can be set as a reflective electrode, and the light emitted from the light-emitting layer LG2 exits through the cathode LG3. If the sub-pixel is formed as a bottom light-emitting structure, the cathode LG3 can be set as a reflective electrode, and the light emitted from the light-emitting layer LG2 exits through the array layer ZL.

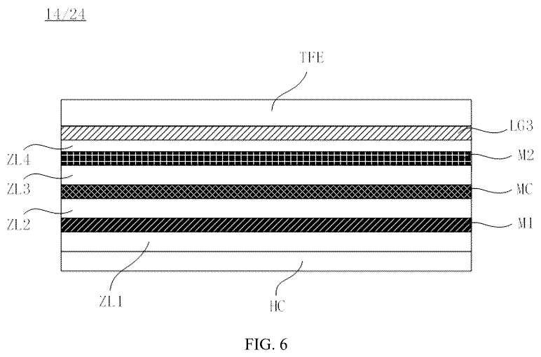

FIG. 6 is a structural schematic diagram of a film layer of a connection structure according to an embodiment of the present disclosure.

In some embodiments, both the film layer structures of the first connection structure 14 and the second connection structure 24 can be shown in FIG. 6, including a first metal layer M1, a capacitor plate layer MC, and a second metal layer M2, where the capacitor plate layer MC is located between the first metal layer M1 and the second metal layer M2, and the second metal layer M2 is located on a side of the first metal layer M1 away from the buffer layer HC. In the diagram of the film layer structure of the first connection structure 14, the buffer layer HC may be the first buffer layer 12, and in the diagram of the film layer structure of the second connection structure 24, the buffer layer HC may be the second buffer layer 22.

In an example, as shown in FIG. 6, the first connection structure 14 and the second connection structure 24 further include a first inorganic layer ZL1 located on a side of the first metal layer M1 close to the buffer layer HC, a capacitor dielectric layer ZL2 located between the first metal layer M1 and the capacitor plate layer MC, an intermediate dielectric layer ZL3 located between the capacitor plate layer MC and the second metal layer M2, and a second inorganic layer ZL4 located on a side of the second metal layer M2 away from the buffer layer HC.

In the first connection structure 14 and the second connection structure 24, the first metal layer M1 may include a scan signal line, the second metal layer M2 may include a data signal line and a power signal line, and the capacitor plate layer MC may include a power signal line and a reset signal line.

The sensing signal line may be arranged in any one of the first metal layer M1, the capacitor plate layer MC, and the second metal layer M2.

Moreover, as shown in FIG. 6, a cathode LG3 is further provided on a side of the second inorganic layer ZL4 away from the buffer layer HC. The cathode LG3 can be directly provided on the second inorganic layer ZL4. The cathode in the connection structure can be electrically connected to the cathode of the sub-pixels in the same substrate, to achieve a common cathode for the sub-pixels in the same substrate. An encapsulation layer TFE is provided on a side of the cathode LG3 away from the buffer layer HC to protect the internal devices.

In combination with FIG. 5 and FIG. 6, in the film layer of the connection structure and the film layer of the sub-pixels, the same film layer can be prepared by the same material and the same process.

In some embodiments, as shown in FIG. 1 and FIG. 2, in the first region 101, an elastic modulus of the first buffer layer 12 is different from an elastic modulus of the second buffer layer 22. In the second region 102, an elastic modulus of the first buffer layer 12 is different from an elastic modulus of the second buffer layer 22.

That is, in the same region, the elastic moduli of the first buffer layer 12 and the second buffer layer 22 which are oppositely arranged are different.

It can be understood that if the elastic moduli of objects are different, their stretching deformation amounts may be different.

In the embodiments of the present disclosure, by setting the elastic modulus of the first buffer layer 12 to be different from the elastic modulus of the second buffer layer 22 in the same region, it is beneficial to achieve different stretching amounts of the first buffer layer 12 and the second buffer layer 22 in the same direction in the corresponding region, which is beneficial for making the first-type sub-pixels 131 and the second-type sub-pixels 231 staggered from each other in a direction perpendicular to the plane where the display panel 01 is arranged in the first region 101 and the second region 102, thereby improving the display quality of the display panel 01 after it is stretched.

Alternatively, as shown in FIG. 2, in the first region 101, an elastic modulus of the first buffer layer 12 is greater than an elastic modulus of the second buffer layer 22. In the second region 102, an elastic modulus of the first buffer layer 12 is less than an elastic modulus of the second buffer layer 22.

Based on this arrangement manner, a stretching amount of part of the first buffer layer 12 in the first substrate 10 can be greater than a stretching amount of the corresponding part of the second buffer layer 22 in the second substrate 20; and a stretching amount of the other part of the first buffer layer 12 in the first substrate 10 can be less than a stretching amount of the corresponding part of the second buffer layer 22 in the second substrate 20. While ensuring that the first-type sub-pixels 131 and the second-type sub-pixels 231 can be staggered from each other in the first region 101 and the second region 102, it is also beneficial to make the stretching deformation amount of the first substrate 10 to tend to be consistent with the stretching deformation amount of the second substrate 20, thereby improving the structural stability and aesthetics of the display panel 01.

Alternatively, the elastic modulus of the first buffer layer 12 in the first region 101 is the same as the elastic modulus of the second buffer layer 22 in the second region 102. The elastic modulus of the second buffer layer 22 in the first region 101 is the same as the elastic modulus of the first buffer layer 12 in the second region 102.

For example, as shown in FIG. 1 and FIG. 4, the first buffer layer 12 includes first-type buffer modules 121, and the first-type buffer modules 121 include a first buffer module 1211 located in the first region 101, and a second buffer module 1212 located in the second region 102.

The second buffer layer 22 includes second-type buffer modules 221, and the second-type buffer modules 221 include a third buffer module 2211 located in the first region 101, and a fourth buffer module 2212 located in the second region 102.

The first buffer module 1211 and the fourth buffer module 2212 have a same elastic modulus, and the second buffer module 1212 and the third buffer module 2211 have a same elastic modulus.

As can be seen from the above analysis, in the first region 101, the elastic modulus of the first buffer layer 12 is greater than the elastic modulus of the second buffer layer 22. In the second region 102, the elastic modulus of the first buffer layer 12 is less than the elastic modulus of the second buffer layer 22. Therefore, in the first region 101, the elastic modulus of the first buffer module 1211 is greater than the elastic modulus of the corresponding third buffer module 2211, and in the second region 102, the elastic modulus of the second buffer module 1212 is less than the elastic modulus of the corresponding fourth buffer module 2212.

When the display panel 01 is stretched, in the first region 101, a deformation amount of the third buffer module 2211 in a stretching direction may be greater than a deformation amount of the first buffer module 1211 in the stretching direction, which facilitating making the third buffer module 2211 drive the second encapsulation structure 23 to move a greater distance than the first buffer module 1211 drives the first encapsulation structure 13 to move, thereby facilitating the first-type sub-pixels 131 and the second-type sub-pixels 231 in the first region 101 to be staggered from each other in the direction Z perpendicular to the plane where the display panel 01 is arranged.

In the second region 102, a deformation amount of the second buffer module 1212 in the stretching direction can be greater than a deformation amount of the fourth buffer module 2212 in the stretching direction, which facilitating making the second buffer module 1212 drive the first encapsulation structure 13 to move a greater distance than the fourth buffer module 2212 drives the second encapsulation structure 23 to move, thereby facilitating the first-type sub-pixels 131 and the second-type sub-pixels 231 in the second region 102 to be staggered from each other in the direction Z perpendicular to the plane where the display panel 01 is arranged.

In this way, in the stretched state of the display panel 01, the first-type sub-pixels 131 in the first substrate 10 and the corresponding second-type sub-pixels 231 in the second substrate 20 can be staggered from each other in the direction Z perpendicular to the plane where the display panel 01 is arranged. At this time, the first-type sub-pixels 131 and the second-type sub-pixels 231 are all controlled to emit light, thereby increasing the number of sub-pixels for displaying the picture after the display panel 01 is stretched, and improving the resolution of the display picture after the display panel 01 is stretched.

Moreover, the elastic modulus of the first buffer module 1211 in the first substrate 10 is the same as the elastic modulus of the fourth buffer module 2212 in the second substrate 20, and the elastic modulus of the second buffer module 1212 in the first substrate 10 is the same as the elastic modulus of the third buffer module 2211 in the second substrate 20, which is beneficial to make the sum of the deformation amount of the first buffer module 1211 in the first substrate 10 and the deformation amount of the second buffer module 1212 in the first substrate 10 equal to the sum of the deformation amount of the third buffer module 2211 in the second substrate 20 and the deformation amount of the fourth buffer module 2212 in the second substrate 20 when the display panel 01 is stretched, thereby further making the stretching deformation amount of the first substrate 10 and the stretching deformation amount of the second substrate 20 tend to be consistent, and improving the structural stability and aesthetics of the display panel 01 in the stretched state.

In addition, the first buffer module 1211 in the first region 101 and the fourth buffer module 2212 in the second region 102 can be made of the same material, and the second buffer module 1212 in the first region 101 and the third buffer module 2211 in the second region 102 can be made of the same material, to reduce the number of material types in the display panel 01, thereby facilitating reducing the structural complexity of the display panel 01, simplifying the preparation process of the display panel 01, and reducing the preparation difficulty.

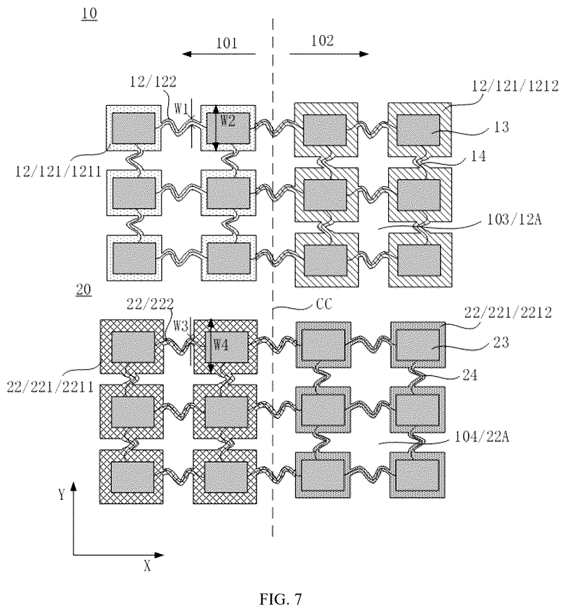

FIG. 7 is another plane comparison schematic diagram of a first substrate and a second substrate according to an embodiment of the present disclosure;

In some embodiments, as shown in FIG. 7, the plurality of first encapsulation structures 13 are arranged in an array along a first direction X and a second direction Y, and the second direction Y intersects with the first direction X.

Exemplarily, one of the first direction X and the second direction Y is a row direction in the display panel 01, and the other of the first direction X and the second direction Y is a column direction in the display panel 01.

Four first encapsulation structures 13 arranged in an array along the first direction X and the second direction Y enclose a third region 103, and the first buffer layer 12 includes a first hollow region 12A located in the third region 103.

That is, the first buffer layer 12 may not be provided in a region surrounded by the four first encapsulation structures 13 arranged in the array.

In the embodiments of the present disclosure, a first hollow region 12A is provided in the third region 103, which is beneficial to increasing the stretching amount of the first buffer layer 12 when the display panel 01 is stretched, thereby facilitating better staggering the first encapsulation structure 13 and the corresponding second encapsulation structure 23, and improving the reliability of the staggered arrangement between the first-type sub-pixels 131 and the second-type sub-pixels 231.

Alternatively, as shown in FIG. 7, in the first substrate 10, any third region 103 includes a first hollow region 12A, to increase the stretchable amount of the first buffer layer 12 to a greater extent.

Please continue to refer to FIG. 7, in some embodiments, the first buffer layer 12 includes a plurality of first-type buffer modules 121 and a plurality of first connection bridges 122, the first-type buffer modules 121 are arranged in correspondence with the first encapsulation structures 13, and the first connection bridge 122 is connected to two adjacent first-type buffer modules 121.

For example, as shown in FIG. 7, a first connection bridge 122 is provided between two adjacent first-type buffer modules 121 along the first direction X, and a first connection bridge 122 is provided between two adjacent first-type buffer modules 121 along the second direction Y.

The first encapsulation structure 13 can be arranged on the first-type buffer module 121, and the first connection structure 14 can be arranged on the first connection bridge 122.

In a direction perpendicular to a plane where the display panel 01 is arranged, a projection area of the first encapsulation structure 13 is not greater than a projection area of the first-type buffer module 121, to ensure the reliability of the first-type buffer module 121 in carrying the first encapsulation structure 13.

For example, as shown in FIG. 7, along a direction perpendicular to a plane where the display panel 01 is arranged, a projection area of the first encapsulation structure 13 is smaller than a projection area of the first-type buffer module 121.

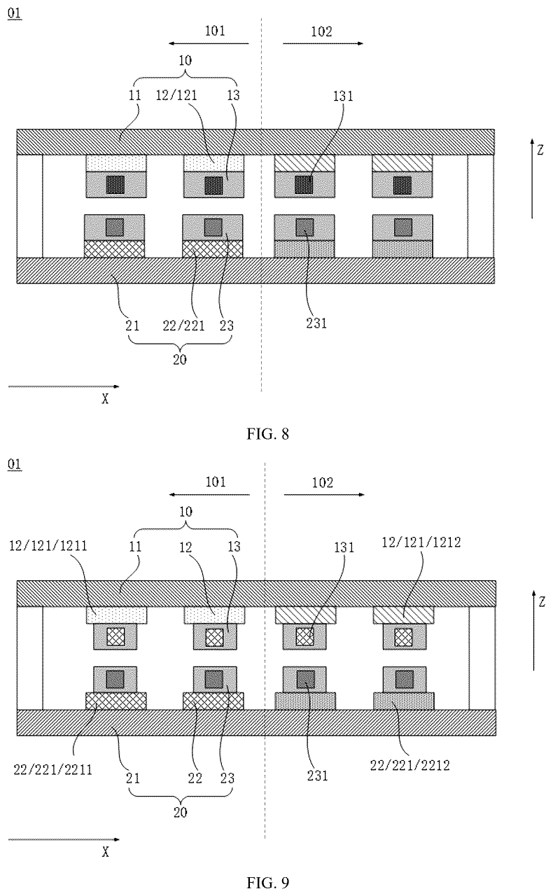

For example, as shown in FIG. 8, which is another structural schematic diagram of a display panel in a contracted state according to an embodiment of the present disclosure, along a direction Z perpendicular to a plane where the display panel 01 is arranged, a projection of the first encapsulation structure 13 coincides with a projection of the first-type buffer module 121 on the same plane.

A width of the first connection bridge 122 is smaller than a width of the first-type buffer module 121 connected thereto in a same direction.

For example, as shown in FIG. 7, in the second direction Y, a maximum width of the first connection bridge 122 extending along the first direction X is W1, and a minimum width of the first-type buffer module 121 connected thereto in the second direction Y is W2, where W1<W2.

In the embodiments of the present disclosure, the first buffer layer 12 can be formed as an island bridge structure, which is beneficial to further increasing the area of the first hollow region 12A, thereby further improving the stretching deformation amount of the first buffer layer 12 and increasing the reliability of the staggered arrangement between the first-type sub-pixel 131 and the second-type sub-pixel 231 in the stretched state.

In some embodiments, as shown in FIG. 7, the plurality of second encapsulation structures 23 are arranged in an array along the first direction X and the second direction Y, and in a contracted state of the display panel 01, the second encapsulation structures 23 are arranged in correspondence with the first encapsulation structures 13.

Four second encapsulation structures 23 arranged in an array along the first direction X and the second direction Y enclose a fourth region 104, and the second buffer layer 22 includes a second hollow region 22A located in the fourth region 104. That is, the second buffer layer 22 may not be provided in a region surrounded by the four second encapsulation structures 23 arranged in the array. The second hollow regions 22A are arranged in correspondence with the first hollow regions 12A.

In the embodiments of the present disclosure, a second hollow region 22A is provided in the fourth region 104, which is beneficial to increasing the stretching amount of the second buffer layer 22 when the display panel 01 is stretched, thereby facilitating better staggering the second encapsulation structure 23 and the corresponding first encapsulation structure 13, and further improving the reliability of the staggered arrangement between the first-type sub-pixels 131 and the second-type sub-pixels 231.

Alternatively, as shown in FIG. 7, in the second substrate 20, any fourth region 104 includes the second hollow region 22A, to increase the stretchable amount of the second buffer layer 12 to a greater extent.

Please continue to refer to FIG. 7, in some embodiments, the second buffer layer 22 includes a plurality of second-type buffer modules 221 and a plurality of second connection bridges 222, the second-type buffer modules 221 are arranged in correspondence with the second encapsulation structures 23, and the second connection bridge 222 is connected to two adjacent second-type buffer modules 221.

For example, as shown in FIG. 7, a second connection bridge 222 is provided between two adjacent second-type buffer modules 221 along the first direction X, and a second connection bridge 222 is provided between two adjacent second-type buffer modules 221 along the second direction Y.

The second encapsulation structure 23 can be arranged on the second-type buffer module 221, and the second connection structure 24 can be arranged on the second connection bridge 222.

In a direction perpendicular to the plane where the display panel 01 is arranged, a projection area of the second encapsulation structure 23 is not greater than a projection area of the second-type buffer module 221, to ensure the reliability of the second-type buffer module 221 in carrying the first encapsulation structure 13.

For example, as shown in FIG. 7, along the direction perpendicular to the plane where the display panel 01 is arranged, the projection area of the second encapsulation structure 23 is smaller than the projection area of the second-type buffer module 221.

For example, as shown in FIG. 8, along the direction Z perpendicular to the plane where the display panel 01 is arranged, a projection of the second encapsulation structure 23 coincides with a projection of the second-type buffer module 221 on the same plane.

A width of the second connection bridge 222 is smaller than a width of the second-type buffer module 221 connected thereto in the same direction.

For example, as shown in FIG. 7, in the second direction Y,, a maximum width of the second connection bridge 222 extending along the first direction X is W3, and a minimum width of the second-type buffer module 221 connected thereto in the second direction Y is W4, where W3<W4.

In the embodiments of the present disclosure, the second buffer layer 22 can be formed as an island bridge structure, which is beneficial to further increasing the area of the second hollow region 22A, thereby further improving the stretching deformation amount of the second buffer layer 22 and increasing the reliability of the staggered arrangement between the first-type sub-pixels 131 and the second-type sub-pixels 231 in the stretched state.

Moreover, in the embodiments of the present disclosure, the structure of the second substrate 20 is similar to that of the first substrate 10, which is beneficial to ensuring that the stretching amount of the first substrate 10 and the stretching amount of the second substrate 20 in the same direction tend to be consistent, thereby improving the reliability of the staggered arrangement between the first-type sub-pixels 131 and the second-type sub-pixels 231 in the stretched state, and meanwhile improving the structural stability and aesthetics of the display panel 01.

In some embodiments, please continue to refer to FIG. 7, the first-type buffer module 121 includes a first buffer module 1211 located in the first region 101, and a second buffer module 1212 located in the second region 102.

An elastic modulus of the first buffer module 1211 is greater than an elastic modulus of the first elastic layer 11, and an elastic modulus of the second buffer module 1212 is less than an elastic modulus of the first elastic layer 11. That is, when the display panel 01 is stretched, a deformation amount of the first buffer module 1211 is less than a deformation amount of the first elastic layer 11, and a deformation amount of the second buffer module 1212 is greater than a deformation amount of the first elastic layer 11.

The second-type buffer module 221 includes a third buffer module 2211 located in the first region 101, and a fourth buffer module 2212 located in the second region 102.

An elastic modulus of the third buffer module 2211 is less than an elastic modulus of the second elastic layer 21, and an elastic modulus of the fourth buffer module 2212 is greater than an elastic modulus of the second elastic layer 21. That is, when the display panel 01 is stretched, a deformation amount of the third buffer module 2211 is greater than a deformation amount of the second elastic layer 21, and a deformation amount of the fourth buffer module 2212 is less than a deformation amount of the second elastic layer 21.

In the embodiments of the present disclosure, the first buffer module 1211 in the first region 101 has a smaller stretching amount relative to the first elastic layer 11, and the third buffer module 2211 in the first region 101 has a larger stretching amount relative to the second elastic layer 21, which is beneficial to improving the reliability of the staggered arrangement between the first encapsulation structure 13 driven by the first buffer module 1211 and the second encapsulation structure 23 driven by the third buffer module 2211 in the first region 101, thereby improving the reliability of the staggered arrangement between the first-type sub-pixels 131 and the second-type sub-pixels 231 in the first region 101.

The second buffer module 1212 in the second region 102 has a larger stretching amount relative to the first elastic layer 11, and the fourth buffer module 2212 in the second region 102 has a smaller stretching amount relative to the second elastic layer 21, which is beneficial to improving the reliability of the staggered arrangement between the first encapsulation structure 13 driven by the second buffer module 1212 and the second encapsulation structure 23 driven by the fourth buffer module 2212 in the second region 102, thereby improving the reliability of the staggered arrangement between the first-type sub-pixels 131 and the second-type sub-pixels 231 in the second region 102.

Moreover, each of the first substrate 10 and the second substrate 20 includes a buffer module with a larger elastic modulus and a buffer module with a smaller elastic modulus, which is beneficial to making the stretching amount of the first substrate 10 and the stretching amount of the second substrate 20 in the same direction tend to be consistent, thereby improving the reliability of the staggered arrangement between the first-type sub-pixels 131 and the second-type sub-pixels 231 in the stretched state, and meanwhile improving the structural stability and aesthetics of the display panel 01.

Alternatively, the elastic modulus of the first elastic layer 11 is the same as the elastic modulus of the second elastic layer 21. In this way, the stretching amount of the first elastic layer 11 can be the same as the stretching amount of the second elastic layer 21, which is beneficial to further ensuring that a length of the first substrate 10 and a length of the second substrate 20 after being stretched tend to be consistent.

Please continue to refer to FIG. 1, in some embodiments, the first-type buffer modules 121 include a plurality of first buffer modules 1211 and a plurality of second buffer modules 1212, and the first buffer modules 1211 and the second buffer modules 1212 are both arranged in correspondence with the first encapsulation structures 13. The second-type buffer modules 221 include a plurality of third buffer modules 2211 and a plurality of fourth buffer modules 2212, and the third buffer modules 2211 and the fourth buffer modules 2212 are arranged in correspondence with the second encapsulation structures 23.

As shown in FIG. 1 and FIG. 7, the first buffer layer 12 and the second buffer layer 22 are both formed as an island bridge structure.

Alternatively, in the contracted state of the display panel 01, along the direction Z perpendicular to the plane where the display panel 01 is arranged, a projection area of the third buffer module 2211 is not less than a projection area of the first buffer module 1211, and a projection area of the second buffer module 1212 is not less than a projection area of the fourth buffer module 2212. That is, in the same region, along the direction Z perpendicular to the plane where the display panel 01 is arranged, a projection area of the buffer module with a smaller elastic modulus is not less than a projection area of the buffer module with a larger elastic modulus.

In this way, when the display panel 01 is stretched, it is beneficial to ensure that the stretching deformation amount of the buffer module with a smaller elastic modulus is larger, which is beneficial to further ensuring the staggered arrangement between the first-type sub-pixels 131 and the second-type sub-pixels 231.

For example, as shown in FIG. 1, along the direction Z perpendicular to the plane where the display panel 01 is arranged, a projection area of the third buffer module 2211 is greater than a projection area of the first buffer module 1211, and a projection area of the second buffer module 1212 is greater than a projection area of the fourth buffer module 2212.

For example, as shown in FIG. 9, which is another structural schematic diagram of a display panel in a contracted state according to an embodiment of the present disclosure, along a direction Z perpendicular to a plane where the display panel 01 is arranged, a projection of the third buffer module 2211 coincides with a projection of the first buffer module 1211 on a same plane, and a projection of the second buffer module 1212 coincides with a projection of the fourth buffer module 2212 on a same plane.

Alternatively, as shown in FIG. 1, in the contracted state of the display panel 01, along the direction Z perpendicular to the plane where the display panel 01 is arranged, a projection of the first-type buffer module 121 on the plane where the first elastic layer 11 is arranged covers a projection of the first encapsulation structure 13 on the plane where the first elastic layer 11 is arranged, and a projection of the second-type buffer module 221 on the plane where the second elastic layer 21 is arranged covers a projection of the second encapsulation structure 23 on the plane where the second elastic layer 21 is arranged.

Since the first-type buffer modules 121 include the first buffer modules 1211 and the second buffer modules 1212 arranged in correspondence with the first encapsulation structure 13, respectively, and the second-type buffer modules 221 include the third buffer modules 2211 and the fourth buffer modules 2212 arranged in correspondence with the second encapsulation structure 23, respectively., a projection of the first buffer module 1211 and a projection of the second buffer module 1212 on the plane where the first elastic layer 11 is arranged can both cover a projection of the corresponding first encapsulation structure 13 on the plane where the first elastic layer 11 is arranged, and a projection of the third buffer module 2211 and a projection of the fourth buffer module 2212 on the plane where the second elastic layer 21 is arranged can both cover a projection of the corresponding second encapsulation structure 23 on the plane where the second elastic layer 21 is arranged.

Based on this arrangement manner, on the one hand, the carrying capacity of the first-type buffer module 121 on the first encapsulation structure 13 and the carrying capacity of the second-type buffer module 221 on the second encapsulation structure 23 can be improved, thereby facilitating improving the structural stability of the display panel 01. On the other hand, it is beneficial to improve the ability of the first-type buffer module 121 to drive the first encapsulation structure 13 and the second-type buffer module 221 to drive the second encapsulation structure 23 to be staggered with each other, thereby further improving the reliability of the fully-staggered arrangement between the first-type sub-pixels 131 and the second-type sub-pixels 231 in the stretched state.

In some embodiments, please continue to refer to FIG. 1, in the contracted state of the display panel 01, in the first direction X, a length of the second buffer module 1212 and a length of the third buffer module 2211 are both d1, and a distance between two adjacent second buffer modules 1212 and a distance between two adjacent third buffer modules 2211 are both h1. A length of the first buffer module 1211 and a length of the fourth buffer module 2212 are both d2, and a distance between two adjacent first buffer modules 1211 and a distance between two adjacent fourth buffer modules 2212 are both h2.

h1+d1=h2+d2, h1>0.5dl, h2−k*d2, and 0.8≤k≤1.2.

Based on this arrangement manner, in the first region 101 and the second region 102, the sum of the length of the first-type buffer module 121 and the distance between two adjacent first-type buffer modules 121 is equal to the sum of the length of the corresponding second-type buffer module 221 and the distance between two corresponding adjacent second-type buffer modules 221. Moreover, a distance between two adjacent first-type buffer modules and a distance between two adjacent second-type buffer modules 221 are not too small. As a result, when the display panel 01 is stretched, the first-type buffer module 121 and the second-type buffer module 221 respectively drive the corresponding first encapsulation structure 13 and the second encapsulation structure 23 to be staggered with each other, thereby further improving the reliability of the fully-staggered arrangement between the first-type sub-pixels 131 and the second-type sub-pixels 231.

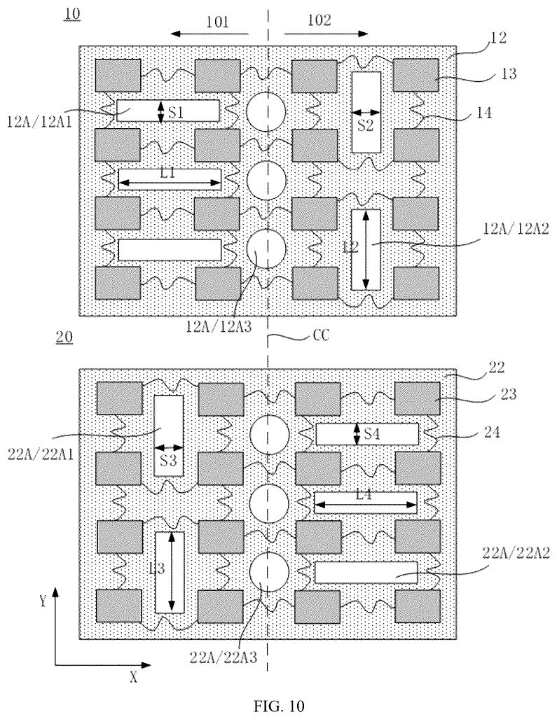

FIG. 10 is another plane comparison schematic diagram of a first substrate and a second substrate according to an embodiment of the present disclosure.

As shown in FIG. 10, in some embodiments, the first buffer layer 12 includes a first hollow region 12A, and the first hollow region 12A includes a first hollow sub-region 12A1 located in the first region 101, and a second hollow sub-region 12A2 located in the second region 102.

The second buffer layer 22 includes a second hollow region 22A, and the second hollow region 22A includes a third hollow sub-region 22A1 located in the first region 101, and a fourth hollow sub-region 22A2 located in the second region 102.

A shape of the first hollow sub-region 12A1 is different from a shape of the third hollow sub-region 22A1, and a shape of the second hollow sub-region 12A2 is different from a shape of the fourth hollow sub-region 22A2. Different shapes mean that orthographic projections of the two on the plane where the display panel 01 is arranged cannot overlap after being translated together.

That is, in the first region 101, a shape of the first hollow region 12A is different from a shape of the second hollow region 22A, and in the second region 102, a shape of the first hollow region 12A is different from a shape of the second hollow region 22A.

In the embodiments of the present disclosure, the shape of the first hollow region 12A is set to be different from the shape of the second hollow region 22A in the corresponding region, it is beneficial to achieve different stretching amounts of the first buffer layer 12 and the second buffer layer 22 in the same direction in the corresponding region, so that in the first region 101 and the second region 102, the first-type sub-pixels 131 and the second-type sub-pixels 231 can be staggered with each other in the direction perpendicular to the plane where the display panel 01 is arranged, thereby improving the display quality of the display panel 01 after being stretched.

Alternatively, as shown in FIG. 10, in the first direction X, a length L1 of the first hollow sub-region 12A1 is greater than a width S3 of the third hollow sub-region 22A1, and a width S2 of the second hollow sub-region 12A2 is less than a length L4 of the fourth hollow sub-region 22A2.

In the second direction Y, a width S1 of the first hollow sub-region 12A1 is less than a length L3 of the third hollow sub-region 22A1, and a length L2 of the second hollow sub-region 12A2 is greater than a width S4 of the fourth hollow sub-region 22A2. The first direction X intersects with the second direction Y.

Based on this arrangement manner, when the display panel 01 is stretched along the first direction X, in the first region 101, a deformation amount of the second buffer layer 22 may be greater than a deformation amount of the first buffer layer 12, and in the second region 102, a deformation amount of the first buffer layer 12 may be greater than a deformation amount of the second buffer layer 22.

When the display panel 01 is stretched along the second direction Y, in the first region 101, a deformation amount of the first buffer layer 12 may be greater than a deformation amount of the second buffer layer 22, and in the second region 102, a deformation amount of the second buffer layer 22 may be greater than a deformation amount of the first buffer layer 12.

In this way, when the display panel 01 is stretched, it is beneficial to ensure that in the first region 101 and the second region 102, the first buffer layer 12 and the second buffer layer 22 correspondingly arranged respectively drive the first encapsulation structure 13 and the second encapsulation structure 23 to be staggered with each other, thereby achieving the full-staggered arrangement between the first-type sub-pixels 131 and the second-type sub-pixels 231 in the stretched state of the display panel 01.

Moreover, based on this arrangement manner, in a same stretching direction, both the first buffer layer 12 and the second buffer layer 22 include parts with larger stretching amounts and smaller stretching amounts, which is also beneficial to make a stretching amount of the first buffer layer 12 and a stretching amount of the second buffer layer 22 tend to be consistent in the same direction, thereby improving the structural stability and aesthetics of the display panel 01.

Alternatively, as shown in FIG. 10, a shape of the first hollow sub-region 12A1 is the same as a shape of the fourth hollow sub-region 22A2, and a shape of the second hollow sub-region 12A2 is the same as a shape of the third hollow sub-region 22A1. The same shape means that orthographic projections of the two on the plane where the display panel 01 is arranged can coincide after being translated together.

Based on this arrangement manner, on one hand, it is beneficial to reduce the structural complexity of the first hollow region 12A and the second hollow region 22A, thereby reducing the preparation difficulty of the display panel 01 and saving the cost. On the other hand, it is beneficial to further make a stretching amount of the first buffer layer 12 and a stretching amount of the second buffer layer 22 in the same direction tend to be consistent, and ensure that a length of the first substrate 10 and a length of the second substrate 20 are consistent after the display panel 01 is stretched.

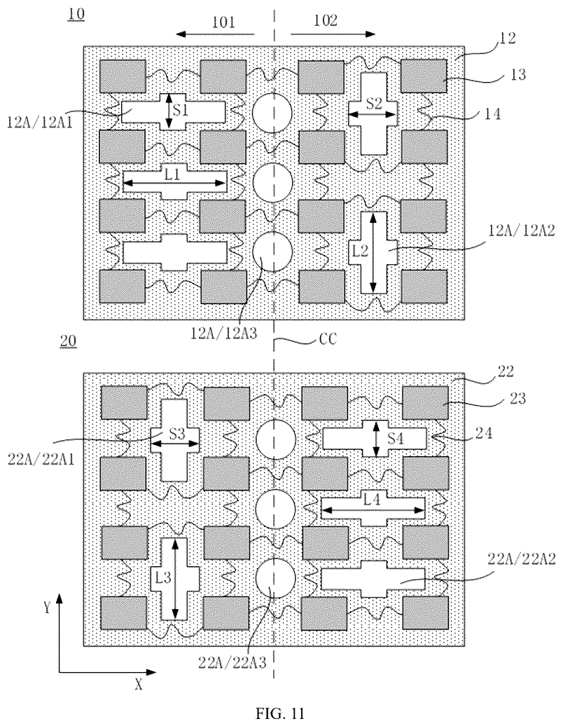

Alternatively, as shown in FIG. 11, which is another plane comparison schematic diagram of a first substrate and a second substrate according to an embodiment of the present disclosure, the first hollow sub-region 12A1, the second hollow sub-region 12A2, the third hollow sub-region 22A1 and the fourth hollow sub-region 22A2 are all in a “cross” shape.

The maximum length L1 of the first hollow sub-region 12A1 in the first direction X is greater than the maximum width S1 of the first hollow sub-region 12A1 in the second direction Y, the maximum width S2 of the second hollow sub-region 12A2 in the first direction X is less than the maximum length L2 of the second hollow sub-region 12A2 in the second direction Y, the maximum width S3 of the third hollow sub-region 22A1 in the first direction X is less than the maximum length L3 of the third hollow sub-region 22A1 in the second direction Y, and the maximum length L4 of the fourth hollow sub-region 22A2 in the first direction X is greater than the maximum width S4 of the fourth hollow sub-region 22A2 in the second direction Y.

In this way, it is beneficial to increase the stretching deformation amounts of the first buffer layer 12 and the second buffer layer 22 in the corresponding region, and is beneficial to further ensure the full-staggered arrangement between the first-type sub-pixels 131 and the second-type sub-pixels 231 in the stretched state of the display panel 01.

Please continue to refer to FIG. 10 and FIG. 11, in some embodiments, the display panel 01 includes a first virtual central axis CC extending along the second direction Y, and the first virtual central axis CC is located between the first region 101 and the second region 102.

The first hollow region 12A further includes a fifth hollow sub-region 12A3, and the second hollow region 22A further includes a sixth hollow sub-region 22A3. The first virtual central axis CC extends through the fifth hollow sub-region 12A3 and the sixth hollow sub-region 22A3.

That is, the first buffer layer 12 and the second buffer layer 22 further include hollow regions located on the position of the first virtual central axis CC.

It has found that when the display panel 01 is stretched, a tensile force at the middle position of the display panel 01 is smaller, and the middle region of the display panel 01 is prone to an issue where the first-type sub-pixels 131 and the second-type sub-pixels 231 cannot be completely staggered.

In view of this, in the embodiments of the present disclosure, the fifth hollow sub-region 12A3 and the sixth hollow sub-region 22A3 are located in the region where the first virtual central axis CC is arranged, which is beneficial to increasing the stretching deformation amount of the first buffer layer 12 and the second buffer layer 22 at the region where the first virtual central axis CC is arranged, thereby facilitating improving the reliability of the first buffer layer 12 and the second buffer layer 22 drive, respectively, the first encapsulation structure 13 and the second encapsulation structure 23, to be completely staggered in the middle region of the display panel 01, and improving the reliability of the fully-staggered arrangement of the first-type sub-pixels 131 and the second-type sub-pixel 231s in the middle region of the display panel 01.

Alternatively, as shown in FIG. 10 and FIG. 11, the fifth hollow sub-region 12A3 and the sixth hollow sub-region 22A3 are both formed as a circular shape. In this way, when the display panel 01 is stretched in multiple directions, the first-type sub-pixels 131 and the second-type sub-pixels 231 located in the middle region of the display panel 01 can be effectively staggered.

Alternatively, the first buffer layer 12 and the second buffer layer 22 are made of the same material. In this way, it is beneficial to simplify the preparation process of the first buffer layer 12 and the second buffer layer 22, and reducing the preparation cost of the display panel 01.

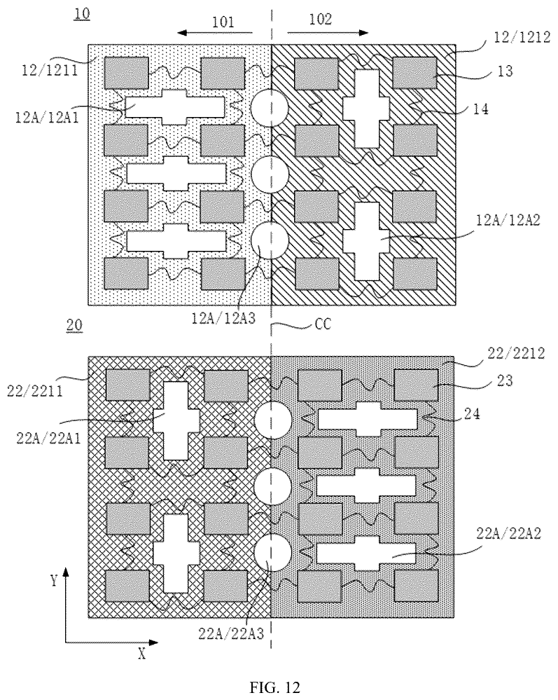

FIG. 12 is another plane comparison schematic diagram of a first substrate and a second substrate according to an embodiment of the present disclosure.

In some embodiments, as shown in FIG. 12, in the first region 101, the first buffer layer 12 and the second buffer layer 22 are made of different materials, and an elastic modulus of the first buffer layer 12 is greater than an elastic modulus of the second buffer layer 22. In the second region 102, the first buffer layer 12 and the second buffer layer 22 are made of different materials, and the elastic modulus of the first buffer layer 12 is less than the elastic modulus of the second buffer layer 22.

In the embodiments of the present disclosure, when the first hollow sub-region 12 A1 and the third hollow sub-region 22 A1 are arranged in the first region 101, the elastic modulus of the first buffer layer 12 is greater than the elastic modulus of the second buffer layer 22, so that when the display panel 01 is stretched along the first direction X, it is beneficial to further increase a difference between a stretching deformation amount of the second buffer layer 22 and a stretching deformation amount of the first buffer layer 12 in the first region 101.

When the second hollow sub-region 12 A2 and the fourth hollow sub-region 22 A2 are arranged in the second region 102, the elastic modulus of the first buffer layer 12 is less than the elastic modulus of the second buffer layer 22, so that when the display panel 01 is stretched along the first direction X, it is beneficial to further increase a difference between a stretching deformation amount of the second buffer layer 22 and a stretching deformation amount of the first buffer layer 12 in the second region 102.

In this way, in the embodiments of the present disclosure, it is beneficial to further increase the difference between a stretching deformation amount of the first buffer layer 12 and a stretching deformation amount of the second buffer layer 22 in the corresponding region, thereby facilitating further improve the reliability of the full-staggered arrangement of the first-type sub-pixels 131 and the second-type sub-pixels 231 in the stretched state.

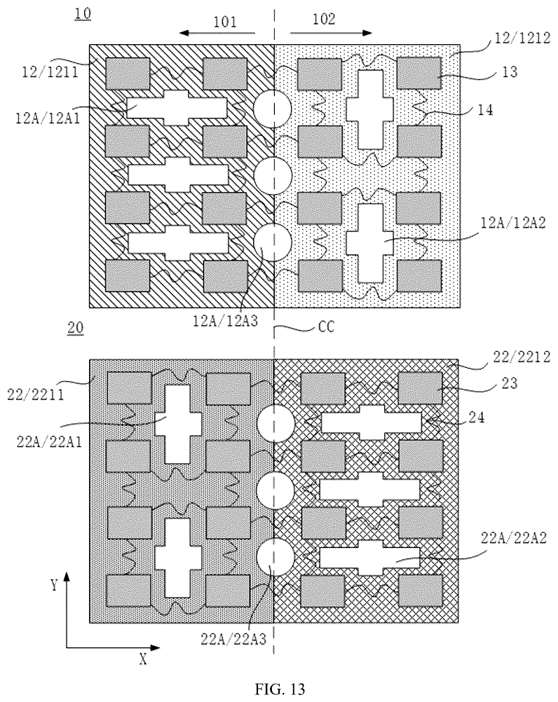

It should be noted that, in some other embodiments, when the display panel 01 is stretched along the second direction Y, as shown in FIG. 13, which is another plane comparison schematic diagram of a first substrate and a second substrate according to an embodiment of the present disclosure, in the first region 101, the elastic modulus of the first buffer layer 12 is less than the elastic modulus of the second buffer layer 22. In the second region 102, the elastic modulus of the first buffer layer 12 is greater than the elastic modulus of the second buffer layer 22.

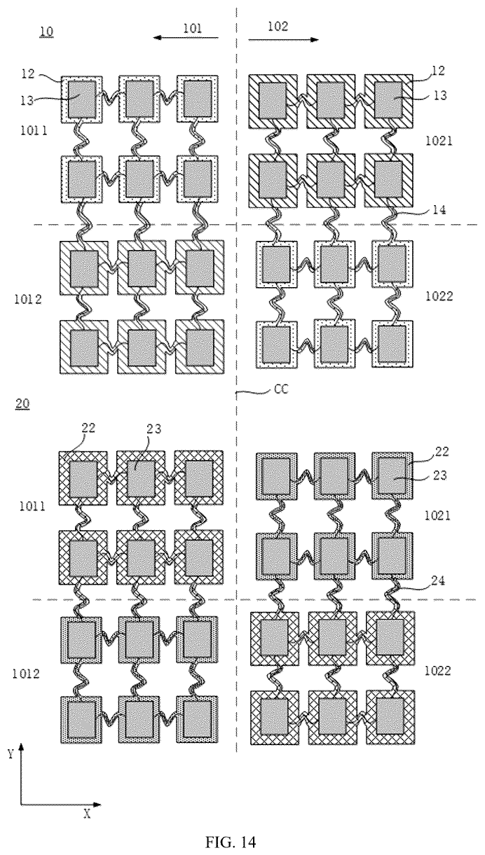

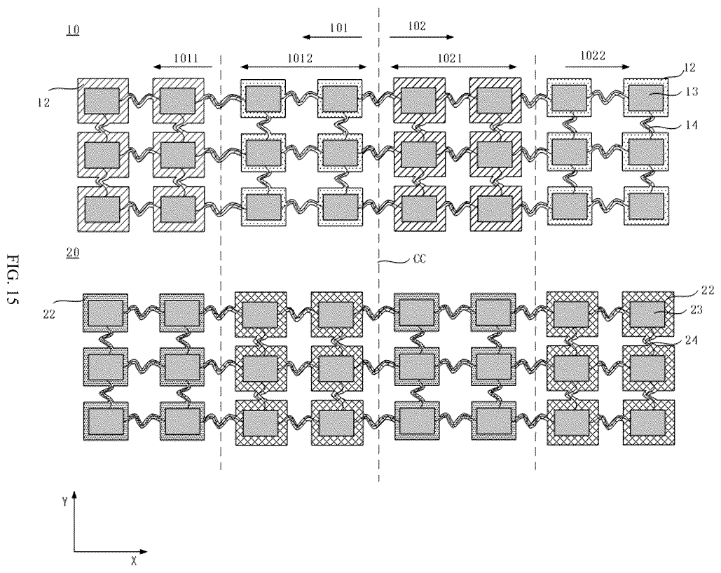

FIG. 14 is another plane comparison schematic diagram of a first substrate and a second substrate according to an embodiment of the present disclosure.

In some embodiments, as shown in FIG. 14, the first region 101 includes a first sub-region 1011 and a second sub-region 1012 extending along a second direction Y, and the second region 102 includes a third sub-region 1021 and a fourth sub-region 1022 that are arranged along the second direction Y. The second direction Y intersects with the first direction X.

In any one of the first sub-region 1011, the second sub-region 1012, the third sub-region 1021 and the fourth sub-region 1022, the first buffer layer 12 and the second buffer layer 22 have different stretching amounts in the same direction.

In the embodiments of the present disclosure, in any one of the first sub-region 1011, the second sub-region 1012, the third sub-region 1021, and the fourth sub-region 1022, the first buffer layer 12 and the second buffer layer 22 have different stretching amounts in the same direction, so that the stretching amount of each sub-region can be flexibly set according to the stretching direction of the display panel 01, which is beneficial to completely staggering the first-type sub-pixels 131 and the second-type sub-pixels 231 when the display panel 01 is stretched in different directions.

Alternatively, as shown in FIG. 14, the first sub-region 1011 and the third sub-region 1021 are arranged along the first direction X, and the second sub-region 1012 and the fourth sub-region 1022 are arranged along the first direction X. The first buffer layer 12 located in the first sub-region 1011 and the fourth sub-region 1022 has a different stretching amount in the same direction from the first buffer layer 12 located in the second sub-region 1012 and a different stretching amount in the same direction from the first buffer layer 12 located in the third sub-region 1021.

The second buffer layer 22 located in the first sub-region 1011 and the fourth sub-region 1022 has a different stretching amount in the same direction from the second buffer layer 22 located in the second sub-region 1012, and a different stretching amount in the same direction from the second buffer layer 22 located in the third sub-region 1021.

Based on this arrangement manner, in the first direction X and the second direction Y, buffer layers with different stretching amounts can be alternately arranged, which is beneficial to further realizing that when the display panel 01 is stretched in different directions, the first-type sub-pixels 131 and the second-type sub-pixels 231 can be completely staggered.

For example, as shown in FIG. 14, in the first sub-region 1011, the elastic modulus of the first buffer layer 12 is greater than the elastic modulus of the second buffer layer 22; in the second sub-region 1012, the elastic modulus of the first buffer layer 12 is less than the elastic modulus of the second buffer layer 22; in the third sub-region 1021, the elastic modulus of the first buffer layer 12 is less than the elastic modulus of the second buffer layer 22; and in the fourth sub-region 1022, the elastic modulus of the first buffer layer 12 is greater than the elastic modulus of the second buffer layer 22.

The first buffer layer 12 in the first sub-region 1011, the first buffer layer 12 in the fourth sub-region 1022, the second buffer layer 22 in the second sub-region 1012, and the second buffer layer 22 in the third sub-region 1021 can be made of a same material, and the second buffer layer 22 in the first sub-region 1011, the second buffer layer 22 in the fourth sub-region 1022, the first buffer layer 12 in the second sub-region 1012, and the first buffer layer 12 in the third sub-region 1021 can be made of a same material.

In this way, when the display panel 01 is stretched in different directions, it is beneficial to completely stagger the first-type sub-pixels 131 and the second-type sub-pixels 231, and also to reduce the complexity of the display panel 01 and the preparation cost.

FIG. 15 is another plane comparison schematic diagram of a first substrate and a second substrate according to an embodiment of the present disclosure.

As shown in FIG. 15, in some embodiments, the first region 101 includes a first sub-region 1011 and a second sub-region 1012 that are arranged along the first direction X, and the second region 102 includes a third sub-region 1021 and a fourth sub-region 1022 that are arranged along the first direction X. The first sub-region 1011, the second sub-region 1012, the third sub-region 1021, and the fourth sub-region 1022 are arranged in sequence.

In any one of the first sub-region 1011, the second sub-region 1012, the third sub-region 1021 and the fourth sub-region 1022, the first buffer layer 12 and the second buffer layer 22 have different stretching amounts in the same direction.

The first buffer layer 12 in the first sub-region 1011 has the same stretching amount in the same direction as the first buffer layer 12 in the third sub-region 1021, and has a different stretching amount in the same direction from the first buffer layer 12 in the second sub-region 1012. The first buffer layer 12 in the second sub-region 1012 has the same stretching amount in the same direction as the first buffer layer 12 in the fourth sub-region 1022.

The second buffer layer 22 in the first sub-region 1011 has the same stretching amount in the same direction as the second buffer layer 22 in the third sub-region 1021, and has a different stretching amount in the same direction from the second buffer layer 22 in the second sub-region 1012. The second buffer layer 22 in the second sub-region 1012 has the same stretching amount in the same direction as the second buffer layer 22 in the fourth sub-region 1022.

In the embodiments of the present disclosure, the buffer layers with different stretching amounts can be alternately arranged along the first direction X, so that when the display panel 01 is stretched along the first direction X, it is easier to make the overall stretching amount of the first buffer layer 12 and the overall stretching amount of the second buffer layer 22 tend to be consistent, which not only allows the first-type sub-pixels 131 and the second-type sub-pixels 231 to be completely staggered, but also facilitates further ensuring that the length of the first substrate 10 and the length of the second substrate 20 are the same in the stretched state.

In some embodiments, the display panel 01 is formed as a double-sided display structure, and the first-type sub-pixels 131 and the second-type sub-pixels 231 are both formed as a bottom light-emitting structure. For example, the structure of the display panel 01 can be as shown in FIG. 1, FIG. 4 and FIG. 8.

In this way, the first-type sub-pixels 131 can emit light toward the first elastic layer 11, and the second-type sub-pixels 231 can emit light toward the second elastic layer 21, thereby achieving double-sided display of the display panel 01.

In some embodiments, the first elastic layer 11 and the second elastic layer 21 can both be made of a light-transmitting elastic material, which not only can achieve the stretching of the display panel 01, but also can avoid affecting the light emission of the sub-pixels.

In some other embodiments, as shown in FIG. 1 and FIG. 2, the display panel 01 is formed as a single-sided display structure, and the first substrate 10 is located on a side of the second substrate 20 facing the light-emitting surface of the display panel 01. That is, the display panel 01 can display a picture on the side of the first substrate 10.

The first-type sub-pixels 131 are formed as a bottom light-emitting structure, and the second-type sub-pixels 231 are formed as a top light-emitting structure.

That is, both the first-type sub-pixels 131 and the second-type sub-pixels 231 emit light toward a side of the first elastic layer 11.

In the embodiments of the present disclosure, the side of the first elastic layer 11 the display panel 01 is a light-emitting side, and the side of the second elastic layer 21 of the display panel 01 is a backlight side, so that the display panel 01 can achieve single-sided display. The first elastic layer 11 may be made of a light-transmitting material to avoid affecting the light emission of the first-type sub-pixels 131 and the second-type sub-pixels 231. The second elastic layer 21 may be made of an opaque material or a material with a low light transmittance to prevent light from leaking out from the side of the second elastic layer 21.

Alternatively, as shown in FIG. 1, in the contracted state of the display panel 01, the first-type sub-pixels 131 emit light, and the second-type sub-pixels 231 do not emit light. Since the first-type sub-pixels 131 are formed as a bottom light-emitting structure, the first-type sub-pixels 131 emit light towards the first elastic layer 11, thereby realizing normal display of the display panel 01 in the contracted state.

In the stretched state of the display panel 01, as shown in FIG. 2, the first-type sub-pixels 131 and the second-type sub-pixels 231 both emit light. Since the first-type sub-pixels 131 and the second-type sub-pixels 231 can be staggered from each other by stretching, the first-type sub-pixels 131 and the second-type sub-pixels 231 can both emit light toward the first elastic layer 11, which can increase the number of sub-pixels of the display picture after being stretched, thereby improving the resolution of the display panel 01 in the stretched state.

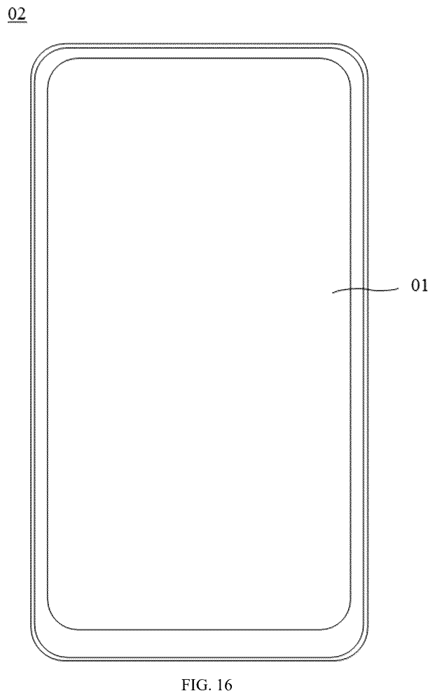

FIG. 16 is a schematic diagram of a display device according to an embodiment of the present disclosure.

An embodiment of the present disclosure provides a display device 02, as shown in FIG. 16, and the display device 02 includes the display panel 01 provided by the above-mentioned embodiments. For example, the display device 02 is an electronic device such as a mobile phone, a tablet computer, a vehicle-mounted display, and a wearable display, which is not specifically limited in the present disclosure.

In the display device 02, in the first region 101 and/or the second region 102, stretching amounts of the first buffer layer 12 and the second buffer layer 22 in the same direction are different. As a result, when the display panel 01 is stretched, in the first region 101 and/or the second region 102, the first buffer layer 12 and the second buffer layer 22 respectively drive the first encapsulation structure 13 and the second encapsulation structure 23 to move different distances, so that the first-type sub-pixels 131 in the first encapsulation structures 13 and the second-type sub-pixels 231 in the second encapsulation structures 23 are staggered from each other in a direction perpendicular to a plane on which the display panel 01 is arranged, which is beneficial for exposing the second-type sub-pixels 231 after the display panel 01 is stretched, to increase the number of sub-pixels for displaying a picture after the display panel 01 is stretched, thereby improving the resolution of the display picture after the display panel 01 is stretched, and improving the display quality.

The above descriptions are merely preferred embodiments of the present disclosure and are not intended to limit the present disclosure. It should be noted that any modifications, equivalent substitutions, improvements, and the like made within the spirit and principle of the present disclosure shall fall within the scope of the present disclosure.

What is claimed is:

1. A display panel, comprising a first substrate and a second substrate opposite to each other;
wherein the first substrate comprises a first elastic layer, a first buffer layer and a plurality of first encapsulation structures, the plurality of first encapsulation structures respectively comprise at least one first-type sub-pixel, the first buffer layer is located between the first elastic layer and the plurality of first encapsulation structures, and the plurality of first encapsulation structures are located on a side of the first elastic layer facing the second substrate;
wherein the second substrate comprises a second elastic layer, a second buffer layer, and a plurality of second encapsulation structures, the plurality of second encapsulation structures respectively comprise at least one second-type sub-pixel, the second buffer layer is located between the second elastic layer and the plurality of second encapsulation structures, and the plurality of second encapsulation structures are located on a side of the second elastic layer facing the first substrate; and
wherein the display panel comprises a first region and a second region that are arranged along a first direction, and in the first region and/or the second region, the first buffer layer and the second buffer layer have different stretching amounts in a same direction.

2. The display panel according to claim 1, wherein in the first region, an elastic modulus of the first buffer layer is different from an elastic modulus of the second buffer layer; and
in the second region, an elastic modulus of the first buffer layer is different from an elastic modulus of the second buffer layer.

3. The display panel according to claim 2, wherein in the first region, the elastic modulus of the first buffer layer is greater than the elastic modulus of the second buffer layer; and
in the second region, the elastic modulus of the first buffer layer is less than the elastic modulus of the second buffer layer.

4. The display panel according to claim 3, wherein the first buffer layer comprises first-type buffer modules, and the first-type buffer modules comprise a first buffer module located in the first region, and a second buffer module located in the second region;
the second buffer layer comprises second-type buffer modules, and the second-type buffer modules comprise a third buffer module located in the first region, and a fourth buffer module located in the second region; and
wherein the first buffer module and the fourth buffer module have a same elastic modulus, and the second buffer module and the third buffer module have a same elastic modulus.

5. The display panel according to claim 4, wherein the plurality of first encapsulation structures are arranged in an array along the first direction and a second direction, and the second direction intersects with the first direction; and
four of the plurality of first encapsulation structures arranged in an array along the first direction and the second direction enclose a third region, and the first buffer layer comprises a first hollow region located in the third region.

6. The display panel according to claim 5, wherein the first buffer layer comprises a plurality of first-type buffer modules and a plurality of first connection bridges, the plurality of first-type buffer modules are arranged in correspondence with the plurality of first encapsulation structures, and one of the plurality of first connection bridges is connected to two adjacent first-type buffer modules; and
wherein a width of one of the plurality of first connection bridge is less than a width of a respective one of the plurality of first-type buffer modules connected thereto in a same direction.

7. The display panel according to claim 5, wherein the plurality of second encapsulation structures are arranged in an array along the first direction and the second direction; and
four of the plurality of second encapsulation structures arranged in an array along the first direction and the second direction enclose a fourth region, and the second buffer layer comprises a second hollow region located in the fourth region.

8. The display panel according to claim 7, wherein the second buffer layer comprises a plurality of second-type buffer modules and a plurality of second connection bridges, the plurality of second-type buffer modules are arranged in correspondence with the plurality of second encapsulation structures, and one of the plurality of second connection bridges is connected to two adjacent second-type buffer modules; and
wherein a width of one of the plurality of second connection bridge is less than a width of a respective one of the plurality of second-type buffer modules connected thereto in a same direction.

9. The display panel according to claim 4, wherein an elastic modulus of the first buffer module is greater than an elastic modulus of the first elastic layer, and an elastic modulus of the second buffer module is less than the elastic modulus of the first elastic layer; and
an elastic modulus of the third buffer module is less than an elastic modulus of the second elastic layer, and an elastic modulus of the fourth buffer module is greater than the elastic modulus of the second elastic layer.

10. The display panel according to claim 4, wherein the first-type buffer modules comprise a plurality of first buffer modules and a plurality of second buffer modules, and the plurality of first buffer modules and the plurality of second buffer modules are all arranged in correspondence with the plurality of first encapsulation structures; and the second-type buffer modules comprise a plurality of third buffer modules and a plurality of fourth buffer modules, and the plurality of third buffer modules and the plurality of fourth buffer modules are all arranged in correspondence with the plurality of second encapsulation structures.

11. The display panel according to claim 10, wherein in a contracted state of the display panel, along the first direction, a length of one of the plurality of second buffer modules and a length of one of the plurality of third buffer modules are both d1, a distance between two adjacent second buffer modules and a distance between two adjacent third buffer modules are both h1, a length of one of the plurality of first buffer modules and a length of one of the plurality of fourth buffer modules are both d2, and a distance between two adjacent first buffer modules and a distance between two adjacent fourth buffer modules are both h2; and
wherein h1+d1=h2+d2, h1>0.5d1, h2=k*d2, and 0.8≤k≤1.2.

12. The display panel according to claim 10, wherein in a contracted state of the display panel, along a direction perpendicular to a plane of the display panel, a projection area of one of the plurality of third buffer modules is not less than a projection area of a respective one of the plurality of first buffer modules, and a projection area of one of the plurality of second buffer modules is not less than a projection area of a respective one of the plurality of fourth buffer modules.

13. The display panel according to claim 10, wherein in a contracted state of the display panel, along a direction perpendicular to a plane of the display panel, a projection of one of the first-type buffer modules on a plane of the first elastic layer covers a projection of a respective one of the plurality of first encapsulation structures on the plane of the first elastic layer; and a projection of one of the second-type buffer modules on a plane of the second elastic layer covers a projection of a respective one of the plurality of the second encapsulation structures on the plane of the second elastic layer.

14. The display panel according to claim 1, wherein the first buffer layer comprises a first hollow region, and the first hollow region comprises a first hollow sub-region located in the first region, and a second hollow sub-region located in the second region; and
the second buffer layer comprises a second hollow region, and the second hollow region comprises a third hollow sub-region located in the first region, and a fourth hollow sub-region located in the second region; and
wherein a shape of the first hollow sub-region is different from a shape of the third hollow sub-region, and a shape of the second hollow sub-region is different from a shape of the fourth hollow sub-region.

15. The display panel according to claim 14, wherein in the first direction, a length of the first hollow sub-region is greater than a width of the third hollow sub-region, and a width of the second hollow sub-region is less than a length of the fourth hollow sub-region; and
in a second direction, a width of the first hollow sub-region is less than a length of the third hollow sub-region, a length of the second hollow sub-region is greater than a width of the fourth hollow sub-region, and the second direction intersects the first direction.

16. The display panel according to claim 15, wherein a shape of the first hollow sub-region is the same as a shape of the fourth hollow sub-region, and a shape of the second hollow sub-region is the same as a shape of the third hollow sub-region.

17. The display panel according to claim 15, further comprising: a first virtual central axis extending along the second direction, wherein the first virtual central axis is located between the first region and the second region; and
wherein the first hollow region further comprises a fifth hollow sub-region, the second hollow region further comprises a sixth hollow sub-region, and the first virtual central axis passes through the fifth hollow sub-region and the sixth hollow sub-region.

18. The display panel according to claim 15, wherein in the first region, an elastic modulus of the first buffer layer is greater than an elastic modulus of the second buffer layer; and in the second region, an elastic modulus of the first buffer layer is less than an elastic modulus of the second buffer layer.

19. The display panel according to claim 1, wherein the first region comprises a first sub-region and a second sub-region that are arranged along a second direction, the second region comprises a third sub-region and a fourth sub-region that are arranged along the second direction, and the second direction intersects with the first direction; and
the first buffer layer and the second buffer layer in any one of the first sub-region, the second sub-region, the third sub-region and the fourth sub-region have different stretching amounts in a same direction.

20. The display panel according to claim 1, wherein the display panel is formed as a double-sided display structure, and the at least one first-type sub-pixel and the at least one second-type sub-pixel both include a bottom light-emitting structure.

21. The display panel according to claim 1, wherein the display panel is formed as a single-sided display structure, and the first substrate is located on a side of the second substrate facing a light-emitting surface of the display panel; and
wherein the at least one first-type sub-pixel includes a bottom light-emitting structure, and the at least one second-type sub-pixel includes a top light-emitting structure.

22. A display device, comprising a display panel;
wherein the display panel comprises a first substrate and a second substrate opposite to each other;
wherein the first substrate comprises a first elastic layer, a first buffer layer and a plurality of first encapsulation structures, the plurality of first encapsulation structures respectively comprise at least one first-type sub-pixel, the first buffer layer is located between the first elastic layer and the plurality of first encapsulation structures, and the plurality of first encapsulation structures are located on a side of the first elastic layer facing the second substrate;
wherein the second substrate comprises a second elastic layer, a second buffer layer, and a plurality of second encapsulation structures, the plurality of second encapsulation structures respectively comprise at least one second-type sub-pixel, the second buffer layer is located between the second elastic layer and the plurality of second encapsulation structures, and the plurality of second encapsulation structures are located on a side of the second elastic layer facing the first substrate; and
wherein the display panel comprises a first region and a second region that are arranged along a first direction, and in the first region and/or the second region, the first buffer layer and the second buffer layer have different stretching amounts in a same direction.
